(19) United States
(12) Patent Application Publication
(10) Pub. No.: US 2026/0130192 A1
(43) Pub. Date: May 7, 2026

(54) WAFER-LEVEL CAVITY PACKAGE WITH BACKSIDE TERMINATION

(71) Applicant: Qorvo US, Inc., Greensboro, NC (US)

(72) Inventors: Hao Dong, Longwood, FL (US); Charles E. Carpenter, Orlando, FL (US)

(21) Appl. No.: 19/320,181

(22) Filed: Sep. 5, 2025

Related U.S. Application Data
(60) Provisional application No. 63/715,788, filed on Nov. 4, 2024.

(51) Int. Cl. H01L 23/48; H01L 21/768; H01L 23/04; H01L 23/34

(52) U.S. Cl. CPC H10W 20/20; H10W 20/023; H10W 40/00; H10W 76/12

(57) ABSTRACT

A wafer-level cavity package with backside termination is disclosed. In one aspect, a package includes an air cavity that is adjacent to a substrate. Input/output (I/O) vias extend from the circuits in the air cavity through the substrate for connection to external pads for the package. A cap covers the air cavity and does not include metal conductors therethrough. By routing the vias through the substrate instead of the cap, numerous advantages are realized, including better thermal pathing, improved structural integrity of the cap, reductions in die and module stress, tighter frequency variation, enhanced yield, and options for shrinking overall package geometry.

### PRIORITY APPLICATION

The present application is related to U.S. Provisional Patent Application Ser. No. 63/715,788, filed on Nov. 4, 2024, and entitled “WAFER-LEVEL CAVITY PACKAGE WITH BACKSIDE TERMINATION,” the contents of which are incorporated herein by reference in their entirety.

### BACKGROUND

### I. Field of the Disclosure

The technology of the disclosure relates generally to circuit packages that contain an air cavity that may contain a circuit, such as an acoustic filter.

### II. Background

Computing devices abound in modern society, and more particularly, mobile communication devices have become increasingly common. The prevalence of these mobile communication devices is driven in part by the many functions that are now enabled on such devices. Increased processing capabilities in such devices means that mobile communication devices have evolved from pure communication tools into sophisticated mobile entertainment centers, thus enabling enhanced user experiences. Concurrent with the advent of the myriad functions available to such devices, there has been increased pressure to minimize the size of circuitry that supports the various functions. Current operating frequencies may rely on acoustic filters positioned in an air cavity within a circuit package as part of transmission chains (or receive chains) that provide wireless communication. These acoustic filters are subjected to pressures of being the same size as other circuits within the mobile communication device. Finding an appropriate compromise between performance, structural integrity, thermal paths, and the like provides room for innovation.

### SUMMARY

Aspects disclosed in the detailed description include a wafer-level cavity package with backside termination. In particular, a package includes an air cavity adjacent to a substrate. Input/output (I/O) vias extend from the circuits in the air cavity through the substrate for connection to external pads for the package. A cap covers the air cavity and does not include metal conductors therethrough. By routing the vias through the substrate instead of the cap, numerous advantages are realized, including better thermal pathing, improved structural integrity of the cap, reductions in die and module stress, tighter frequency variation, enhanced yield, and options for shrinking overall package geometry.

In this regard, in one aspect, a package is disclosed. The package includes a substrate, a backside termination node on a first side of the substrate, and a cap positioned over the substrate on a second side opposite the first side of the substrate, wherein the cap and the second side delimit an air cavity. The package also includes a circuit positioned on the second side of the substrate in the air cavity, a through-substrate via electrically coupled to the circuit, and the backside termination node, wherein the through-substrate via does not go through the cap.

In another aspect, a method of forming a package is disclosed. The method includes placing a circuit on a substrate, forming an air cavity over the circuit using a cap on the substrate, and providing a backside termination through the substrate and not through the cap.

In another aspect, a communication device is disclosed. The communication device includes a transceiver comprising a package. The package includes a substrate, a backside termination node on a first side of the substrate, and a cap positioned over the substrate on a second side opposite the first side of the substrate, wherein the cap and the second side delimit an air cavity. The package also includes a circuit positioned on the second side of the substrate in the air cavity, a through-substrate via electrically coupled to the circuit, and the backside termination node, wherein the through-substrate via does not go through the cap.

### BRIEF DESCRIPTION OF THE DRAWINGS

FIG. 1 is a cross-section elevational view of a conventional cavity containing a package on a module laminate with vias through the cap of the cavity;

FIG. 2 is a cross-section elevational view of a cavity containing a package with the vias through the substrate according to aspects of the present disclosure;

FIG. 3 is a graph showing modeled test results of improved self-heating of an air cavity compared to a conventional air cavity;

FIG. 4 is a flowchart illustrating an exemplary process for dissipating heat using the package of FIG. 2; and

FIG. 5 is a block diagram of a communication device, which may include a package with an acoustic filter according to FIG. 2, according to the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that although the terms first, second, etc. may be used herein to describe various elements, these elements should not be limited by these terms. These terms are only used to distinguish one element from another. For example, a first element could be termed a second element, and similarly, a second element could be termed a first element without departing from the scope of the present disclosure. As used herein, the term “and/or” includes any and all combinations of one or more of the associated listed items.

It will be understood that when an element, such as a layer, region, or substrate, is referred to as being “on” or extending “onto” another element, it can be directly on or extend directly onto the other element, or intervening elements may also be present. In contrast, when an element is referred to as being “directly on” or extending “directly onto” another element, no intervening elements are present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, no intervening elements are present. It will also be understood that when an element is referred to as being “connected” or “coupled” to another element, it can be directly connected or coupled to the other element, or intervening elements may be present. In contrast, when an element is referred to as being “directly connected” or “directly coupled” to another element, no intervening elements are present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

In keeping with the above admonition about definitions, the present disclosure uses transceiver in a broad manner. Current industry literature uses “transceiver” in two ways. The first way uses transceiver broadly to refer to a plurality of circuits that send and receive signals. Exemplary circuits may include a baseband processor, an up/down conversion circuit, filters, amplifiers, couplers, and the like coupled to one or more antennas. A second way, used by some authors in the industry literature, refers to a circuit positioned between a baseband processor and a power amplifier circuit as a transceiver. This intermediate circuit may include the up/down conversion circuits, mixers, oscillators, filters, and the like but generally does not include the power amplifiers. As used herein, the term transceiver is used in the first sense. Where relevant to distinguish between the two definitions, the terms “transceiver chain” and “transceiver circuit” are used respectively.

Additionally, to the extent that the term “approximately” is used in the claims, it is herein defined to be within five percent (5%).

Aspects disclosed in the detailed description include a wafer-level cavity package with backside termination. In particular, a package includes an air cavity adjacent to a substrate. Input/output (I/O) vias extend from the circuits in the air cavity through the substrate for connection to external pads for the package. A cap covers the air cavity and does not include metal conductors therethrough. By routing the vias through the substrate instead of the cap, numerous advantages are realized, including better thermal pathing, improved structural integrity of the cap, reductions in die and module stress, tighter frequency variation, enhanced yield, and options for shrinking overall package geometry.

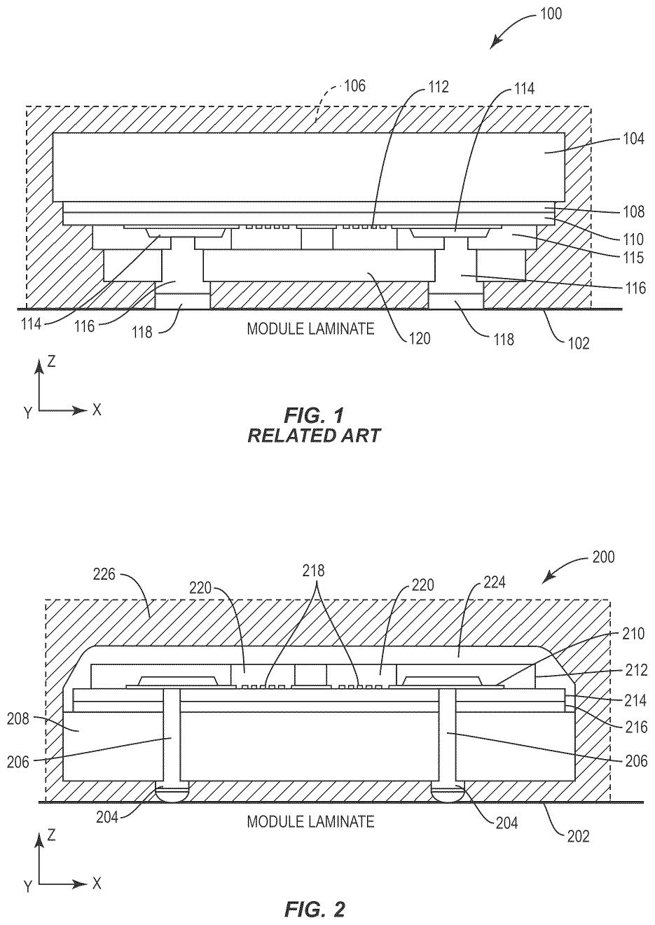

Before addressing aspects of the present disclosure, a brief overview of a conventional package with a conventional air cavity is provided with reference to FIG. 1. A discussion of aspects of the present disclosure begins below with reference to FIG. 2.

In this regard, FIG. 1 illustrates a package 100 that sits on (in the z-axis) a module laminate 102. While only a single line is shown for module laminate 102, it should be appreciated that it has a non-zero z-axis dimension and may include conductors, insulators, surface-mounted elements, and the like. The package 100 has a substrate 104, which may be covered by an overmold 106. The substrate 104 may be a material such as silicon and may have an insulator layer 108, such as silicon dioxide thereon (in the z-axis direction). The insulator layer 108 may have a manufacturing surface 110, such as lithium niobate or lithium tantalate disposed thereon. Interdigital transducer (IDT) fingers 112 (such as may be present in a surface acoustic wave (SAW) filter) or other circuitry may be positioned on the manufacturing surface 110. Under bump metallization 114 positioned in cavity walls 115 may couple to copper (or other metal) posts 116 that couple to conductors (not shown) in the module laminate 102 through solder bumps 118 or the like. Relevantly, the copper posts 116 extend through a cap 120.

The presence of the copper posts 116 through the cap 120 imposes some requirements on the material of the cap 120. Specifically, the cap 120 must be photosensitive to allow the creation of channels through which the copper posts 116 extend. This requirement means that the cap 120 will likely be a polymer, which is generally a poor thermal conductor. Further, such materials have thermal properties (e.g., coefficient thermal expansion (CTE)) that are substantially different from the substrates of the package 100. This difference becomes an issue as the circuits generate waste heat. The heat cannot travel “up” through the substrate 104 because the overmold 106 provides no path for the heat to exit the package 100. Thus, heat must travel from the circuit to the copper posts 116, down through the cap 120, and out to the module laminate 102. This heat path means that both the substrate 104 and the cap 120 are being heated (and at different CTEs), which results in large stress being placed on the cap 120. In extreme cases or after sufficient thermal cycling, the cap 120 may crack or fail. As device miniaturization puts pressure on the package 100 to shrink, there is a limit on how much the cap 120 can be reduced without completely compromising the structural integrity of the cap 120.

Aspects of the present disclosure invert the terminations of the circuitry relative to the package 100. That is, instead of going through the cap 120, the terminations go through the substrate to form bottomside terminations. The terminations are facilitated by through-silicon vias (TSVs) through a silicon substrate. This inversion allows better heat transfer and changes the requirements on the materials of the cap, which allows for many more design options when making engineering compromises, as explained in greater detail below.

In this regard, FIG. 2 illustrates a package 200, which attaches to a module laminate 202 by solder connections 204, also referred to herein more generically as backside termination nodes. The solder connections 204 couple to TSVs 206 that extend through a silicon substrate 208 to couple to busbar 210 (which may have UBM (not shown)) in cavity sidewalls 212. Thus, the solder connections 204 are effectively positioned on a first side of the substrate 208. The cavity sidewalls 212 may be separated from the substrate 208 by a manufacturing surface 214 and/or an insulator 216. The manufacturing surface 214 may be a piezoelectric material. When present, the insulator 216 is between the substrate 208 and the manufacturing surface 214. Circuitry 218 may be positioned within air cavity 220 on the manufacturing surface 214 or a second side of the substrate 208. A cap 224 may form part of the enclosing walls of the air cavity 220. That is, the cap 224, the cavity sidewalls 212, and the substrate 208 (with or without the surface 214 and insulator 216) may delimit the air cavity 220. An overmold material 226 may cover the cap 224 and extend down to the module laminate 202.

By virtue of not having to route posts through the cap 224, the cap 224 may be made from a variety of materials, which may have different attractive properties. For example, the cap 224 does not have to be photosensitive and may have a lower CTE, closer to the CTE of the substrate 208. The cap 224 may have a higher modulus film and may be thinner in the z-axis than previously required. The change in CTE may reduce the stress on the cap 224, allowing the overall size to be smaller. In an exemplary aspect, inorganic material (e.g., fillers) may be used with polymer materials to achieve a desired composite material having desirable characteristics. In short, the material may be 100% inorganic, 100% organic, or a combination of both types of material (e.g., fillers).

Additionally, the substrate 208 now acts to help pull heat from the circuitry 218 laterally through the substrate 208 toward the TSV 206 to assist in extracting heat from the package 200. Note further that the TSV 206 may be positioned directly underneath the circuitry 218 (not shown), which may further assist in pulling heat away from the circuitry 218.

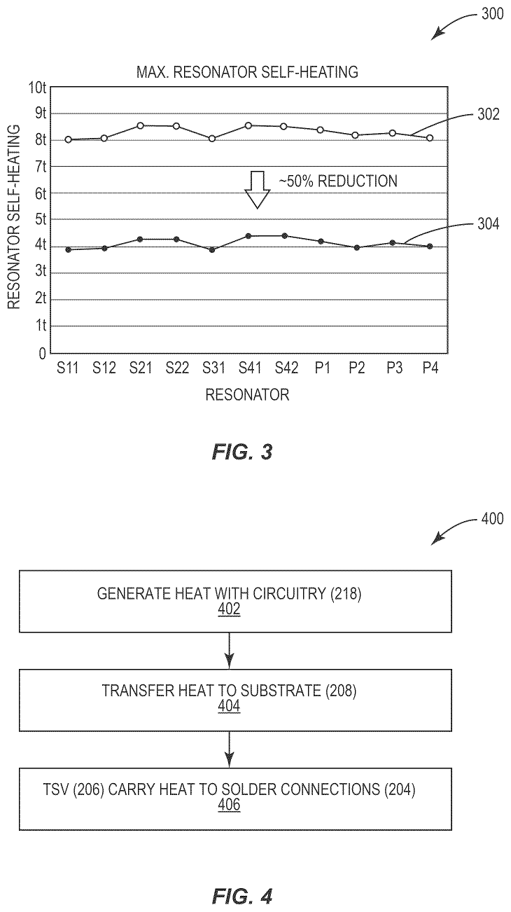

Modeling shows that there is substantial heat reduction in this structure, as is better seen in graph 300 of FIG. 3. The y-axis is the self-heating value with a generic unit t, and the x-axis represents the nodes of the resonator or acoustic filter. Line 302 is the traditional structure of FIG. 1, and line 304 is the package 200. The reduction is approximately 50%.

A process 400 of removing the heat is set forth with reference to FIG. 4. In particular, heat is generated by the circuitry 218 within the cavity (block 402). The heat transfers from the circuitry 218 to the substrate 208 (block 404) and the TSVs 206. The TSVs carry the heat to the solder connections 204 (block 406) and into the module laminate 202.

The wafer-level cavity package with backside termination, according to aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

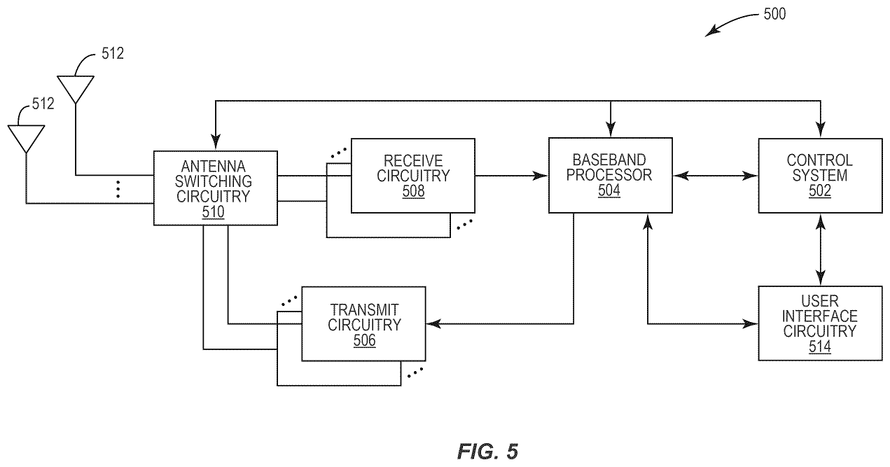

FIG. 5 is a schematic diagram of an exemplary communication device 500 wherein the air cavity packages of the present disclosure can be provided. Herein, the communication device 500 can be any type of communication device, such as those listed above as well as access points, base stations (e.g., eNB or gNB), and any other type of wireless communication devices that support wireless communications, such as cellular, wireless local area network (WLAN), Bluetooth, Ultra-wideband (UWB), and near field communications.

More particularly, the communication device 500 will generally include a control system 502, a baseband processor 504, transmit circuitry 506, receive circuitry 508, antenna switching circuitry 510, multiple antennas 512, and user interface circuitry 514. Both the transmit circuitry 506 and the receive circuitry 508 may include filters and more particularly may include acoustic filters that use air cavities and may be formed in packages according to the present disclosure. In a non-limiting example, the control system 502 can be a field-programmable gate array (FPGA) or an application-specific integrated circuit (ASIC), as an example. In this regard, the control system 502 can include at least a microprocessor(s), an embedded memory circuit(s), and a communication bus interface(s). The receive circuitry 508 receives radio frequency signals via the antennas 512 and through the antenna switching circuitry 510 from one or more base stations. A low noise amplifier and a filter of the receive circuitry 508 cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 504 processes the digitized received signal to extract the information or data bits conveyed in the received signal. This processing typically comprises demodulation, decoding, and error correction operations. The baseband processor 504 is generally implemented in one or more digital signal processors (DSPs) and ASICs.

For transmission, the baseband processor 504 receives digitized data, which may represent voice, data, or control information, from the control system 502, which it encodes for transmission. The encoded data is output to the transmit circuitry 506, where a digital-to-analog converter(s) (DAC) converts the digitally encoded data into an analog signal, and a modulator modulates the analog signal onto a carrier signal that is at a desired transmit frequency or frequencies. A power amplifier will amplify the modulated carrier signal to a level appropriate for transmission and deliver the modulated carrier signal to the antennas 512 through the antenna switching circuitry 510 to the antennas 512. The multiple antennas 512 and the replicated transmit and receive circuitries 506, 508 may provide spatial diversity. Modulation and processing details will be understood by those skilled in the art.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications, as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

What is claimed is:

1. A package comprising:
a substrate;
a backside termination node on a first side of the substrate;
a cap positioned over the substrate on a second side opposite the first side of the substrate, wherein the cap and the second side delimit an air cavity;
a circuit positioned on the second side of the substrate in the air cavity; and
a through-substrate via electrically coupled to the circuit and the backside termination node, wherein the through-substrate via does not go through the cap.

2. The package of claim 1, wherein the circuit is an acoustic filter.

3. The package of claim 1, wherein the substrate is silicon and the through-substrate via is a through-silicon via (TSV).

4. The package of claim 1, wherein the through-substrate via is positioned directly beneath the circuit.

5. The package of claim 1, further comprising cavity sidewalls coupling the substrate to the cap.

6. The package of claim 1, wherein the backside termination node comprises a solder bump.

7. The package of claim 1, further comprising a manufacturing surface on the second side of the substrate.

8. The package of claim 1, further comprising an insulator layer on the second side of the substrate.

9. The package of claim 1, wherein the substrate is configured to provide a thermal path for heat generated in the circuit from the circuit to the backside termination node.

10. The package of claim 1, wherein the cap comprises an inorganic material.

11. The package of claim 1, wherein the cap comprises an organic material.

12. The package of claim 1, wherein the cap comprises a combination of organic and inorganic materials.

13. The package of claim 1, wherein the cap comprises a non-photosensitive material.

14. A method of forming a package, comprising:
placing a circuit on a substrate;
forming an air cavity over the circuit using a cap on the substrate; and
providing a backside termination through the substrate and not through the cap.

15. A communication device comprising:
a transceiver comprising a package, the package comprising:
a substrate;
a backside termination node on a first side of the substrate;
a cap positioned over the substrate on a second side opposite the first side of the substrate, wherein the cap and the second side delimit an air cavity;
a circuit positioned on the second side of the substrate in the air cavity; and
a through-substrate via electrically coupled to the circuit and the backside termination node, wherein the through-substrate via does not go through the cap.

16. The communication device of claim 15, wherein the circuit is an acoustic filter.

17. The communication device of claim 15, further comprising a module laminate coupled to the backside termination node.

18. The communication device of claim 15, wherein the substrate is silicon and the through-substrate via is a through-silicon via (TSV).

19. The communication device of claim 15, further comprising cavity sidewalls coupling the substrate to the cap.

20. The communication device of claim 15, further comprising a manufacturing surface on the second side of the substrate.
